(19) United States
(12) Patent Application Publication
(10) Pub. No.: US 2006/0163670 A1
(43) Pub. Date: Jul. 27, 2006

(54) DUAL SILICIDE PROCESS TO IMPROVE DEVICE PERFORMANCE

(75) Inventors: John J. Ellis-Monaghan, Grand Isle, VT (US); Dale W. Martin, Hyde Park, VT (US); William J. Murphy, North Ferrisburgh, VT (US); James S. Nakos, Essex Junction, VT (US); Kirk D. Peterson, Essex Junction, VT (US)

Correspondence Address: SCULLY, SCOTT, MURPHY & PRESSNER, 400 GARDEN CITY PLAZA, GARDEN CITY, NY, 11530, US

(73) Assignee: INTERNATIONAL BUSINESS MACHINES CORPORATION, Armonk, NY (US)

(21) Appl. No.: 10/905,945

(22) Filed: Jan. 27, 2005

(51) Int. Cl. H01L 29/76

(52) U.S. Cl. 257/388

(57) ABSTRACT

A semiconducting structure and a method of forming thereof, includes a substrate having a p-type device region and an n-type device region; a first-type suicide contact to the n-type device region; the first-type suicide having a work function that is substantially aligned to the n-type device region conduction band; and a second-type silicide contact to the p-type device region; the second-type silicide having a work function that is substantially aligned to the p-type device region valence band. The present invention also provides a semiconducting structure and a method of forming therefore, in which the silicide contact material and silicide contact processing conditions are selected to provide strain based device improvements in pFET and nFET devices.

### FIELD OF THE INVENTION

The present invention relates to metal suicide contacts for use in semiconductor devices, and more particularly to a structure, and a method of forming thereof, having two different metal silicide contacts with two different work functions. The present invention also relates to semiconductor devices, in which the metal of the silicide contact is selected to provide strain based device improvements.

### BACKGROUND OF THE INVENTION

In order to be able to fabricate integrated circuits (ICs) of increased performance than is currently feasible, device contacts must be developed which reduce the electrical contact resistance. A contact is the electrical connection between an active semiconductor device region, e.g., a source/drain or gate of a transistor device at the wafer surface, and a metal layer, which serve as interconnects.

Silicide contacts are of specific importance to IC's, including complementary metal oxide semiconductor (CMOS) devices because of the need to reduce the electrical resistance of the many Si contacts, at the source/drain and gate regions, in order to increase chip performance. Silicides are metal compounds that are thermally stable and provide for low electrical resistivity at the Si/metal interface. Reducing contact resistance improves device speed therefore increasing device performance.

Silicide formation typically requires depositing a metal such as Ni, Co, Pd, Pt, Rh, Ir, Zr, Cr, Hr, Er, Mo or Ti onto the surface of a Si-containing material or wafer. Following deposition, the structure is then subjected to an annealing step using conventional processes such as, but not limited to, rapid thermal annealing. During thermal annealing, the deposited metal reacts with Si forming a metal silicide.

As technologies advance n-type field effect transistors (nFET) and p-type field effect transistors (pFET) are necessarily combined in the same structure, as in complementary field effect transistors (CMOS). In order to minimize the series resistance in both nFET and pFET devices, low resistance contacts are required to both the nFET and pFET devices. Ideally, low resistance suicide contacts to pFET devices have a work function that aligns with the pFET's valence band and low resistance silicide contacts to nFET devices have a work function, which aligns with the nFET's conduction band. Prior contacts to CMOS nFET and pFET device structures utilize contacts formed during a single conductive material deposition, wherein each contact comprises the same material.

Therefore, since one silicide is utilized to form contacts to both the nFET and pFET devices, a tradeoff in contact resistance between the different device types exists, in which a silicide chosen to minimize the contact resistance of one device, for example an nFET, increases the contact resistance of the other device, for example a pFET. As device scaling continues, improvement is needed in the contact resistance of the silicide contacts to the nFET and pFET devices to insure that contact resistance does not dominate the performance of the device.

Additionally, prior contacts have utilized very high dopant concentrations to reduce contact resistance. In current devices, the doping concentration has about reached its physical limits. Therefore, new methods must be devised in order to reduce the contact resistance of the contact.

Further, the continued miniaturization of silicon metal oxide semiconductor field effect transistors (MOSFETs) has driven the worldwide semiconductor industry for the last three decades. However, there are growing signs today that MOSFETs are beginning to reach their traditional scaling limits.

Since it has become increasingly difficult to improve MOSFETs and therefore complementary metal oxide semiconductor (CMOS) device performance through continued scaling, methods for improving performance without scaling have become critical. One approach for doing this is to increase carrier (electron and/or hole) mobilities. One method for increasing carrier mobility is to introduce an appropriate strain into the Si lattice.

The application of stresses or strains changes the lattice dimensions of the Si-containing substrate. By changing the lattice dimensions, the energy gap of the material is changed as well. The change may only be slight in intrinsic semiconductors resulting in only a small change in resistance, but when the semiconducting material is doped, i.e., n-type, and partially ionized, a very small change in the energy bands can cause a large percentage change in the energy difference between the impurity levels and the band edge. Thus, the change in resistance of the material with stress is large.

Prior attempts to provide strain-based improvements of semiconductor substrates have utilized etch stop liners or embedded SiGe structures. N-type channel field effect transistors (nFETs) need tension on the channel for strain-based device improvements, while p-type channel field effect transistors (pFETs) need a compressive force on the channel for strain-based device improvements. Further scaling of semiconducting devices requires that the strain levels produced within the substrate be controlled and that new methods be developed to increase the strain that can be produced.

In view of the state of the art mentioned above, there is a continued need for providing low contact resistance silicide contacts to both nFET and pFET devices, in which the work function of each silicide contact is tailored to provide a low resistance contact to each device. In addition, there is a continued need for providing strained-Si substrates in bulk-Si or SOI substrates in which the substrate can be appropriately strained for both nFET and pFET devices.

### SUMMARY OF THE INVENTION

An object of the present invention is to provide a semiconducting contact structure having reduced resistivity for contacting both nFET and pFET devices, and a method of forming thereof.

Another object of the present invention is to provide a semiconducting contact structure, and a method of forming the semiconductor structure, in which the semiconducting contact structure comprises low resistance metal silicide contacts to both nFET and pFET devices. The term “low resistance metal silicide contacts” is meant to denote silicide contacts having a contact resistance ranging from 1×10⁻⁹ ohm·cm⁻² to about 1×10⁻⁷ ohm·cm⁻².

A further object of the present invention is to provide a semiconducting device, and a method of forming the semiconducting device, in which the silicided contacts of the device are selected to provide strain based device improvements in nFET and pFET devices.

These and other objects and advantages are achieved in the present invention by a method that allows for silicide materials to be selectively deposited to portions of a semiconductor substrate that are subsequently processed to provide nFET or pFET devices. A semiconducting contact structure having reduced resistivity for contacting both nFET and pFET devices can be provided by silicide contacts having work functions that are optimized to the device to which they make electrical contact. The present invention provides silicide contacts to pFET devices having a work function that has a potential close to the valence band of the pFET device and provides silicide contacts to the nFET devices having a work function that has a potential close to the conduction band of the nFET device. Broadly, the inventive structure comprises:

a substrate having p-type devices in a first device region and n-type devices in a second device region;

a first-type suicide contact to said n-type devices in said second device region; said first-type suicide having a work function that is substantially aligned to a conduction band of said n-type devices in said second device region; and

a second-type silicide contact to said p-type devices in said first device region; said second-type silicide having a work function that is substantially aligned to a valence band of said p-type devices in said first device region.

The first-type silicide contact has a work function that is substantially aligned to a conduction band of the nFET devices and the second -type silicide contact has a work function that is substantially aligned to a valence band of the pFET devices.

The second-type silicide contact can comprise suicides such as PtSi, Pt₂Si, IrSi, Pd₂Si, as well as others that have a work function substantially aligned to the valence band of the pFet devices. The first-type silicide contact may comprise CoSi₂, VSi₂, ErSi, ZrSi₂, HfSi, MoSi₂, NiSi, CrSi₂ as well as others that have a work function substantially aligned to the conduction band of the nFet devices. The contact resistance of the first-type silicide contact may range from about 10⁻⁹ ohm·cm⁻² to about 10⁻⁷ ohm·cm⁻². The contact resistance of the second-type silicide ranges from about 10⁻⁹ ohm·cm⁻² to about 10⁻⁷ ohm·cm⁻²

Another aspect of the present invention is a method of forming a semiconductor substrate having low resistance metal silicide contacts to both nFET and pFET devices. Broadly, the inventive method comprises:

forming a first silicide layer on at least a first region of a substrate, the first region of the semiconducting substrate comprising first conductivity type devices, wherein the first silicide layer has a work function substantially aligned with the first conductivity type device's conduction band; and

forming a second silicide layer on at least a second region of the substrate, the second region of the substrate comprising second conductivity type devices, wherein the second silicide layer has a work function substantially aligned with the second conductivity type device's valence band.

The first region of the substrate comprises at least one nFET device and the second region of the substrate comprises at least one pFET device. Forming the first silicide layer on the first region of the substrate includes depositing a first protective material layer atop the first and second region of the substrate. In a next process step, the first protective layer is etched to expose the first region of the substrate. The first protective layer is opened by forming a first patterned block mask atop the first protective layer protecting the portion of the first protective layer atop the second region of the substrate and exposing the portion of the first protective layer atop the first region of the substrate. The first protective layer is then selectively etched to expose the first region of the substrate, wherein a remaining portion of the first protective layer is positioned overlying the second region of the substrate. The first patterned block mask is then removed. A first silicide metal is then deposited on at least the first region of the substrate. The first silicide metal can comprise Co, Er, V, Zr, Hf, Mo, Ni, Cr or a stack of Co/TiN or other metals or metal alloys that form suicides that have the work function substantially aligned to the conduction band of the nFet devices. The first silicide metal is then annealed to convert the first silicide metal to the first silicide layer. Following silicidation the unreacted metal is removed.

Forming the second silicide layer on a second region of said substrate includes depositing a second protective material layer atop the first and second regions of the substrate and then etching the second protective layer to expose the second region of the substrate. Etching the second protective layer comprises forming a second patterned block mask, in which the second patterned block mask protects the first region of the substrate and exposes the second region of the substrate. The second protective layer is then selectively etched to expose the second region of the substrate, wherein a remaining portion of the second protective layer is positioned overlying the first region of the substrate. The second patterned block mask is then removed. A second silicide metal is then deposited on the second region of the substrate. The second silicide metal can be Pt, Ir, Pd or other metals or metal alloys that form suicides that have the work function substantially aligned to the valence band of the pFet devices. The second silicide metal is then annealed to convert the second silicide metal to the second silicide layer. Following silicidation, the unreacted portion of the second silicide metal is removed. The second protective layer is then optionally removed.

The second silicide layer can be formed either before or after formation of the first silicide layer as some embodiments may provide reasons for forming the second silicide layer either before or after formation of the first silicide layer.

In other embodiments of the present method, the number of processing steps may be reduced by reducing the number of block masks utilized to form the first and second metal silicide layers.

In one example, a first silicide metal is blanket deposited atop the substrate and then annealed to produce a silicide layer over the first and second device region. In a next process, step a single protective layer is formed over the first device region and a second silicide metal is formed over the exposed first silicide layer in the second device region. During annealing the second silicide metal intermixes with the first silicide layer in the second device region.

In another example, a single protective layer is formed over a portion of the substrate containing either first conductivity or second conductivity devices and a first silicide layer is formed atop the exposed portion of the substrate. In a next process step, the single protective layer is removed and a second silicide metal is blanket deposited atop the substrate surface including the first silicide layer. During subsequent annealing the second silicide metal atop the second device region is converted to a second silicide layer and the second silicide metal in the first device region intermixes with the first silicide layer.

In another embodiment of the present invention, a semiconductor device is provided in which the silicide contacts to the source and drain regions of the device provide strain based device improvements for pFET and nFET devices. Broadly, and in specific terms, the inventive semiconducting device comprises:

a semiconducting substrate having a first region and a second region;

at least one first type device comprising a first gate region atop a first device channel portion of said semiconducting substrate within said first region, source and drain regions adjacent said first device channel and a first silicide contacting said source, drain and optionally the gate regions. The first silicide contact producing a first strain in said first region of said semiconducting substrate; and

at least one second type device comprising a second gate region atop a second device channel portion of said semiconducting substrate within said second region, source and drain regions adjacent said second device channel and a second silicide contacting said source, drain and optionally the gate regions. The second silicide contact producing a second strain in said second region of said semiconducting substrate, wherein said first strain and said second strain are compressive strains and said first compressive strain is greater than said second compressive strain, or said first strain is a compressive strain and said second strain is a tensile strain, or said first strain is a tensile strain and said second strain is a tensile strain and said first tensile strain is less than said second tensile strain.

In accordance with the present invention, the first type device can be a pFET and the second type device can be an nFET. The pFET devices should have a more compressive internal strain than the nFet. The nFet devices may have either a compressive or tensile strain. The silicide contacts should be optimized to create a differential of silicide volume to the silicon consumed to create this silicide, as this will create the appropriate stresses for each device. For example CoSi₂ has a ratio of silicide volume to silicon consumed of 0.97 which should produce a mildly tensile stress and will benefit the mobility of an nFet. PtSi has a ratio of silicide volume to silicon consumed of 1.5 which should produce a compressive stress and will benefit the mobility of a pFet. Further examples of suicides with a ratio of suicide volume to silicon consumed that would favor mobility in nfets would be CrSi₂ with a ratio of 0.9, IrSi₃ with a ratio of 0.9 and MoSi₂ with a ratio of 0.87, other suicides will also meet this criteria. Further examples of suicides with a ratio of silicide volume to silicon consumed that would favor mobility in pfets would be PdSi with a ratio of 1.45, RhSi with a ratio of 1.35 and YSi with a ratio of 2.13, other suicides will also meet this criteria.

Another way to create this stress differential would be to create 2 phases of silicide from the same base metal, for example Zr₂Si has a ratio of 2.7 and would favor pFets and Zr₅Si₃ has a ratio of 0.25 and would favor nFets.

Yet another method to create this stress differential would be to deposit Co on the nFets and form CoSi₂ with a ratio of 0.97 and deposit a Co alloy with 5% to 25% silicon, which for example depositing Co₂Si to form CoSi₂ would have a ratio of approx 1.29 which would produce a stress favoring the pFets.

In another aspect of the present invention, a method of providing the above described structure is provided. Broadly, and in specific terms, the inventive method for forming a semiconducting structure comprises the steps of:

forming a first silicide layer on at least a first region of a semiconducting substrate, said first region of said semiconducting substrate comprising first conductivity type devices, said first silicide layer producing a first strain within said first region of said semiconducting substrate; and

forming a second silicide layer on at least a second region of said semiconducting substrate, said second region of said semiconducting substrate comprising second conductivity type devices, said first silicide layer produces a second strain within said second region of said semiconducting substrate, wherein said first strain is different from said second strain.

In accordance with the inventive method, the first strain increases carrier mobility in pFET devices and the second strain increases carrier mobility in nFET devices. The first silicide metal may be a silicide produced from a cobalt silicon alloy, Zr, Pt, Pd, Rh or Y or other metals or alloys that produce a ratio of silicide volume to silicon consumed that produce a compressive stress. The second silicide metal may be a silicide produced from Co, Zr, Cr, Ir, Mo or other metals or alloys that produce a ratio of silicide volume to silicon consumed that produce a stress that is more tensile than the stress produced by the first silicide.

### BRIEF DESCRIPTION OF THE DRAWINGS

FIG. 1 depicts (through cross sectional view) one embodiment of the inventive semiconducting structure having nFET and pFET regions, in which an n-type silicide contact comprising CoSi₂, VSi₂, ErSi, ZrSi₂, HfSi, MoSi₂, CrSi₂, Zr₅Si₃, IrSi₃, NiSi, or other suicides optimized for stress or contact resistance for the nFET regions of the substrate and a p-type suicide contact comprising PtSi, Pt₂Si, IrSi, Pd₂Si, CoSi₂, PdSi, RhSi, YSi, Zr₂Si or other suicides optimized for stress or contact resistance for the pFET regions of the substrate of a CMOS structure.

FIG. 2 is a plot of Idlin v. Ioff for pFET devices having low resistance Pt-silicide contacts and Co-silicide contacts.

FIGS. 3-5 depict (through cross sectional view) one embodiment of the inventive method for providing a CMOS structure having low resistance metal suicide contacts to pFET device and a different low resistance metal silicide contacts to nFET device regions with the silicide differences tailored to improve contact resistances for the differing device types.

FIGS. 6-7 depict (through cross sectional view) a second embodiment of the of the inventive method for providing a CMOS structure having low resistance metal silicide contacts to pFET device regions and different low resistance metal silicide contacts to nFET device regions with the silicide differences tailored to improve contact resistances for the differing device types.

FIGS. 8-10 depict (through cross sectional view) a third embodiment of the of the inventive method for providing a CMOS structure having low resistance metal silicide contacts to pFET device regions and a different low resistance metal silicide contacts to nFET device regions with the silicide differences tailored to improve contact resistances for the differing device types.

FIGS. 11-12 depict (through cross sectional view) another embodiment of the present invention in which the pFET and nFET regions of a semiconductor substrate are separately processed to provide silicide contacts that produce strain based device improvements in nFET and pFET devices.

### DETAILED DESCRIPTION OF THE INVENTION

The present invention, which provides a semiconducting structure, and a method of forming thereof, in which the semiconducting structure comprises low contact resistance silicide contacts to both n-type field effect transistors (nFET) and p-type field effect transistor (pFET), will now be described in greater detail by referring to the drawings that accompany the present application. Although the drawings show the presence of only two field effect transistors (FETs) on one substrate, multiple FETs are also within the scope of the present invention.

The present invention provides a semiconducting structure having both nFET and pFET devices, in which the composition of the metal silicide contacts to the nFET devices has a work function substantially aligned with the conduction band of the nFET devices and the composition of the metal suicide contacts to the pFET devices has a work function substantially aligned to the valence band of the pFET devices.

The term “work function substantially aligned with the conduction band” denotes that the work function of the silicide has a potential that is positioned within the band gap of the nFET device, ranging from approximately the middle of the band gap to the conduction band of an n-type material, preferably being closer to the conduction band. Silicide contacts having a work function substantially aligned with the conduction band produce a low contact resistance n-type silicide. The term “low contact resistance n-type silicide” denotes a metal silicide to nFET devices having a contact resistance of less than 10⁻⁷ ohms·cm⁻².

The term “work function substantially aligned with the valence band” denotes that the work function of the silicide has a potential which is positioned within the band gap of the pFET device, ranging from approximately the middle of the band gap to the valence band of a p-type material, preferably being closer to valence band. Silicide contacts having a work function substantially aligned with the valence band produce a low contact resistance p-type silicide. The term “low contact resistance p-type silicide” denotes a metal silicide to a pFET device having a contact resistance of less than 10⁻⁷ ohms·cm⁻².

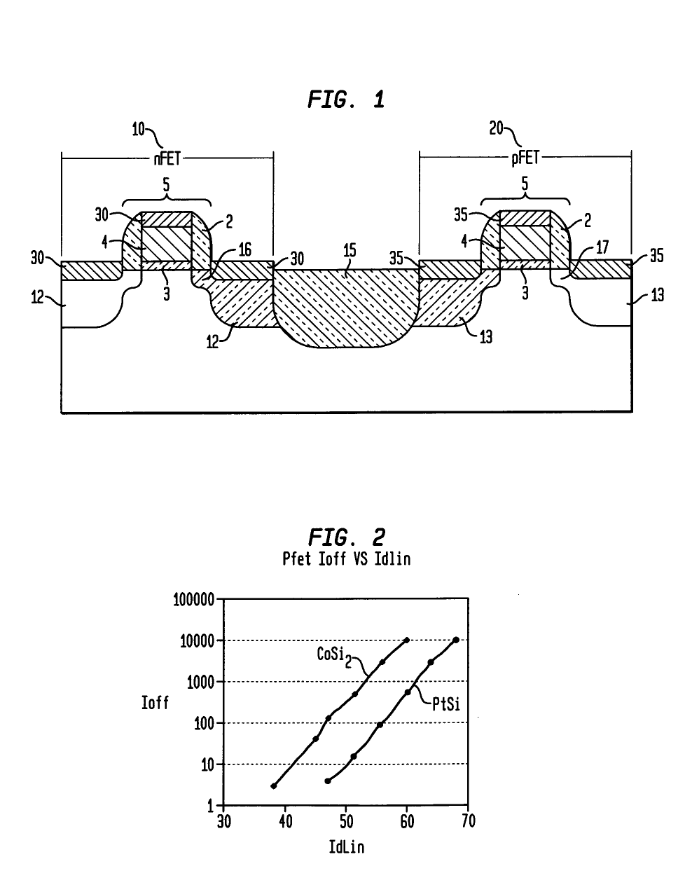

Referring to FIG. 1, the inventive semiconducting device includes an nFET device region 10 and a pFET device region 20. An isolation region 15 may separate the nFET device region 10 and the pFET device region 20. The pFET device region 20 comprises at least one transistor having p-type source/drain regions 13. Each of the transistors further comprises a gate region 5, including a gate conductor 4 atop a gate dielectric 3, in which the gate region 5 is abutted by sidewall spacers 2.

A low resistance p-type silicide contact 35 is formed on both the p-type source/drain/gate contact regions 13, in which the metal of the low resistance p-type silicide contact 35 is selected to produce a metal silicide having a work function potential that is substantially aligned to the valence band of the p-type source/drain 13 material. The low resistance p-type silicide contact 35 positioned on the p-type source/drain regions 13 may be PtSi, Pt₂Si, IrSi, Pd₂Si, CoSi₂, PdSi, RhSi, YSi, Zr₂Si or other suicides optimized for stress or contact resistance for the pFET regions of the substrate so long as the p-type silicide contact 35 has a work function substantially aligned with the valence band of the p-type source/drain material 13. The thickness of the low resistance p-type silicide contact 35 may range from approximately 1 nm to approximately 40 nm.

The nFET device region 10 comprises at least one transistor having n-type source/drain regions 12. Each of the transistors further comprises a gate region 5, including a gate conductor 4 atop a gate dielectric 3, in which the gate region 5 is abutted by sidewall spacers 2.

A low resistance n-type suicide contact 30 is formed on both the n-type source/drain/gate contact regions 12, in which the metal of the low resistance suicide n-type contact is selected to produce a metal suicide having a work function potential that is substantially aligned with the conduction band of the n-type source/drain material 12. The low resistance silicide n-type contact 30 positioned on the n-type source/drain regions 12 may CoSi₂, VSi₂, ErSi, ZrSi₂, HfSi, MoSi₂, CrSi₂, Zr₅Si₃, IrSi₃, NiSi, or other suicides optimized for stress or contact resistance for the nFET regions of the substrate so long as the n-type silicide contact 30 has a work function substantially aligned with the valence band of the n-type source/drain material 12. The thickness of the low resistance silicide n-type contact may range from approximately 1 nm to approximately 40 nm.

The effect of providing p-type silicide contacts to pFET devices is illustrated in the Idlin v. Ioff plot, depicted in FIG. 2. Idlin is a measurement of the current output from the pFET device when the device is turned on. Idlin represents the on-current of the device and is represented by the x-axis. Ioff represent the leakage current through the pFET device when the device is off and is represented by the y-axis. As channel length is reduced, and the on-current increases, the leakage current can increase exponentially.

Increasing the current output (Idlin) from the pFET device increases the device's speed. Current output (Idlin) can be a function of the silicidation process, where the current output is increased by low resistance silicide contacts and decreased by high resistance silicide contacts. The off current of the device (Ioff) is a function of dopant positioning and does not directly depend on the silicidation process.

Therefore, since the output current (Idlin) can be dependent on the silicidation process and the off current (Ioff) is independent of the silicidation process; a decrease in the resistance of the silicide contacts to a device may be measured by an increase in output current (Idlin) for a constant off current (Ioff). Another aspect of the present invention is that by increasing the output current (Idlin) from the device, and keeping the off current (Ioff) constant, the speed and performance of the device may be increased.

Referring to FIG. 2, the output current (Idlin) in uA/um of devices having silicide contacts such as CoSi₂ and PtSi contacts are plotted verses the devices off-current (Ioff). From the plot depicted in FIG. 2, a significant PFET device improvement was achieved with Ptsi contacts as compared to CoSi₂ contacts, wherein for any given off-current on the y-axis, the on-current (Idlin) increased from the CoSi₂ contacts to the PtSi contacts.

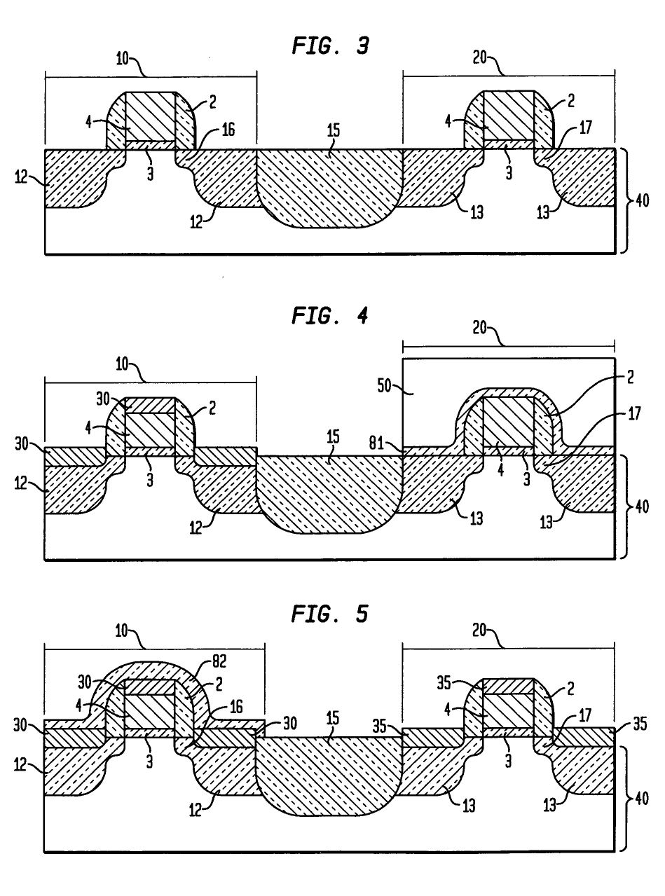

The method for forming the above-described semiconducting structure, as depicted in FIG. 1, is now described with reference to FIGS. 3-10. The first embodiment of the inventive method is depicted in FIGS. 3-5 which depict (through cross sectional view) one embodiment of the inventive method for providing a CMOS structure having low resistance metal suicide contacts to pFET device and a different low resistance metal suicide contacts to nFET device regions with the suicide differences tailored to improve contact resistances for the differing device types.

Referring to FIG. 3, an initial structure is provided having nFET device regions 10 and PFET device regions 20 formed on a substrate 40 of silicon (Si)-containing material. Si-containing materials include, but are not limited to: silicon, single crystal silicon, polycrystalline silicon, silicon germanium, silicon-on-silicon germanium, amorphous silicon, silicon-on-insulator (SOI), silicon germanium-on-insulator (SGOI), and annealed polysilicon. The substrate 40 further includes an isolation region 15 separating the pFET device region 20 from the nFET device region 10. It is noted that although FIG. 3 depicts only one pFET device in the pFET device region 20 and only one nFET device in the nFET device region 10, multiple devices within the nFET device region 10 and pFET device region 20 are also contemplated and therefore within the scope of the present disclosure.

The nFET and pFET devices are formed by utilizing conventional processing steps that are capable of fabricating MOSFET devices. Each device comprises a gate region 5 including a gate conductor 4 atop a gate dielectric 3. At least one set of sidewall spacers 2 may be positioned abutting the gate region 5. Source/drain regions 12, 13 including extension regions 16, 17 are positioned within the substrate 40 and define a device channel. The source/drain regions 12 of the nFET device are n-type doped. The source/drain regions 13 of the pFET device are p-type doped. N-type dopants in the Si-containing substrate are elements from Group V of the Periodic Table of Elements, such as As, Sb, and/or P. P-type dopants in Si-containing substrate are elements from Group III of the Periodic Table of Elements, such as B.

Referring now to FIG. 4, following source/drain anneal, a first nitride protective layer 81 is deposited atop the substrate 40 including the nFET device regions 10 and pFET device regions 20. The first protective layer 81 is deposited using chemical vapor deposition or like processes as typically known within the art. Preferably, the first nitride protective layer 81 is a conformal nitride, such as Si₃N₄, having a thickness ranging from 5 nm to about 20 nm. Although the first protective layer 81 preferably comprises a nitride, the first protective layer 81 may alternatively be an oxide or oxynitride or other suitable dielectrics. The material of the first protective layer 81 is selected to ensure that the first protective layer's 81 integrity is maintained during subsequent silicidation processes.

In a next process step, a first block mask 50 is formed protecting the portion of the first protective layer 81 overlying the second device region (pFET device region 20) and exposing the portion of the first protective layer 81 overlying the first device region (nFET device region 10). The exposed portion of the substrate 40 is then silicided with the appropriate metal suicide to form a low resistance contact to the devices formed therein. In the example depicted in FIG. 4, the first block mask 50 is formed overlying the pFET device region 20 (second device region) leaving the nFET device region 10 (first device region) exposed. In this example an n-type silicide contact is subsequently formed to the devices within the nFET device region 10.

The first block mask 50 is formed by blanket depositing a layer of block mask material layer atop the substrate 40 by low pressure chemical vapor deposition (LPCVD), rapid thermal chemical vapor deposition (RTCVD), or plasma enhanced chemical vapor deposition (PECVD), with PECVD being preferred. The block mask layer is then patterned using conventional photolithography and etch processes. First, a layer of photoresist is deposited atop the entire structure. The photoresist layer is then selectively exposed to light and developed to pattern the photoresist layer to protect the portion of the block mask material layer overlying the first protective layer 81 in the PFET device region 20 of the substrate 40 and exposing the portion of the first protective layer 81 overlying the nFET device region 10.

The pattern is then transferred into the first protective layer 81 using an etch process selective to removing the first protective layer 81 without substantially etching the patterned photoresist or the underlying nFET device region 10. Preferably, the etch process is a directional etch, such as reactive ion etch.

Following etch, the block mask 50 is removed by a chemical strip and/or reactive plasma etch. Once, the block mask 50 has been removed, a cleaning process is then conducted to clean the surface of the exposed portion of the substrate 40, on which the silicide contacts are subsequently formed. The cleaning process is a conventional chemical clean as known by those skilled in the art.

Still referring to FIG. 4, a first silicide layer 30 (low resistance n-type silicide contact 30) is then formed atop the source/drain regions 12 and the gates 4 of the devices in the nFET device region 10. Silicide formation typically requires depositing a metal onto the surface of a Si-containing material. In the embodiment depicted in FIG. 4, the first silicide layer 30 is a low resistance n-type silicide, wherein the first silicide metal forms a silicide having a work function that substantially aligns to the conduction band of the n-type source/drain regions 12 of the Si-containing substrate 40 within the n-type device region 10. Metals that can provide a silicide having a work function substantially aligned to the conduction band of the n-type doped source/drain regions within the Si-containing substrate 40 include Co, Er, V, Zr, Hf, Mo or Cr among others. The silicide metal may be deposited using physical deposition methods, such as plating and sputtering. The metal layer may be deposited to a thickness ranging from about 10 Å to about 100 Å, preferably being 70 Å.

Following deposition, the structure is then subjected to an annealing step using conventional processes such as, but not limited to, rapid thermal annealing. During thermal annealing, the deposited metal reacts with Si forming a metal silicide. In the embodiment depicted in FIG. 4, in which the first silicide metal 30 comprises Co, Er, V, Zr, Hf, Mo, Ni, or Cr, the metal silicide can be CoSi₂, VSi₂, ErSi, ZrSi₂, HfSi, MoSi₂, NiSi, or CrSi₂. The annealing and cleaning details will be optimized by those skilled in the art for each type of silicide. For CoSi₂, the first anneal is completed at a temperature ranging from about 350° C. to about 600° C. for a time period ranging from about 1 second to about 90 seconds. In some embodiments of the present invention, the low resistance n-type metal silicide contacts 30 may further comprise an optional TiN layer.

Silicidation requires that the silicide metal be deposited atop a Si-containing surface. Therefore, silicide forms atop the exposed portions of the Si-containing substrate 40 but does not form atop the first protective layer 81 or the sidewall spacers 2. Silicide may be prevented from forming atop the gate conductor by capping the gate conductor with a dielectric material layer.

The non-reacted silicide metal positioned on sidewall spacers, the isolation region and the first protective layer 81 are then stripped using a wet etch. Preferably, the unreacted first silicide metal is removed by a wet etch selective to removing the non-reacted silicide metal.

An optional second anneal may be needed to reduce the resistivity of the low resistivity n-type silicide contact 30. This second anneal temperature ranges from 600° C. to 800° C., for a time period ranging from about 1 second to 60 seconds. The second anneal can form a disilicide such as, CoSi₂. The thickness of CoSi₂ is about 3.49× the thickness of the originally deposited Co metal.

Following silicidation, the first protective layer 81 may optionally be removed. The first protective layer 81 may be removed by wet or dry etching having high selectivity to removing the first protective layer 81 without substantially etching the pFET or nFET device regions 10, 20.

Referring to FIG. 5, in a next process step a second protective layer 82 is formed over the first device region (nFET device region 10) leaving the second device region (pFET device region 20) exposed. A second silicide layer (low resistivity p-type silicide contact 35) is then formed on the second device region 20 (pFET device region). In the embodiment depicted in FIG. 5, the second protective layer 82 is formed overlying the low resistivity n-type silicide contact 30 in the nFET device region 10 and a low resistivity p-type silicide contact 35 is formed atop the exposed pFET device region 20.

The second protective layer 82 is formed atop the nFET device region 10 using similar materials and processing as used to produce the first protective layer 81, depicted in FIG. 4. Specifically, the second protective layer 82 may be formed using conventional deposition, photolithography and etching. The second protective layer 82 may comprise silicon oxides, silicon carbides, silicon nitrides or silicon carbon-nitrides, or other suitable diaelectric materials, preferably being silicon nitride.

Still referring to FIG. 5, a second silicide metal is then formed atop the pFET device region 20, wherein the second silicide metal produces a second silicide layer having a work function substantially aligned to the valence band of the p-type doped source/drain regions 13 of substrate 40 within the pFET device region 20, thus providing a low resistance p-type silicide contact 35.

Prior to deposition of the second silicide metal, a cleaning process is conducted to clean the surfaces on which the low resistance p-type metal silicide contacts are subsequently formed. The cleaning process preferably comprising buffered or diluted HF.

Low resistance p-type silicide contacts 35, as depicted in FIG. 5, are formed by depositing a layer of a second silicide metal atop the p-type device region 20, wherein the second silicide metal forms a silicide having a work function that is substantially aligned to the valence band of the p-type source/drain regions 13 of the Si-containing substrate 40 within the pFET region 20. Metals that can provide a silicide having a work function substantially aligned to the valance band of the p-type source/drain regions 13 of the Si-containing substrate 40 include Pt, Ir, Pd, as well as others that have the work function substantially aligned to the valence band of the pFet devices. The p-type silicide metal may be deposited using physical deposition methods, such as plating and sputtering. The second silicide metal layer may be deposited to a thickness ranging from about 1 nm to about 10 nm.

Following deposition, the structure is then subjected to an annealing step using conventional processes such as, but not limited to, rapid thermal annealing. During thermal annealing, the deposited second silicide metal reacts with Si forming a metal silicide, such as PtSi, Pt₂Si, IrSi, Pd₂Si. The annealing and cleaning conditions will vary by silicide and are known by those skilled in the art. For PtSi the first anneal is completed at a temperature ranging from about 350° C. to about 600° C. for a time period ranging from about 1 second to about 90 seconds. The thickness of the Pt-silicide is 1.98 times the thickness of the deposited silicide metal.

The unreacted second silicide metal positioned on sidewall spacers 2, the isolation region 15 and second protective layer 82 is then stripped using a wet etch. Preferably, the unreacted Pt is removed using a wet etch comprising nitric acid and HCI. In a next process step, the second protective layer 82 can be removed by wet or dry etching having high selectivity to removing the second protective layer 82 without substantially etching the nFET and pFET device regions 10, 20.

Following silicide formation, the substrate 40 may be processed using conventional back end of the line (BEOL) processing. For example, a layer of dielectric material can be blanket deposited atop the entire substrate and planarized, in which interconnects are formed to the low resistivity n-type and p-type silicide contacts 30, 35.

The blanket dielectric may be selected from the group consisting of silicon-containing materials such as SiO₂, Si₃N₄, SiOₓN_{y}, SiC, SiCO, SiCOH, and SiCH compounds; the above-mentioned silicon-containing materials with some or all of the Si replaced by Ge; carbon-doped oxides; boron and phosphorus doped oxides; inorganic oxides; inorganic polymers; hybrid polymers; organic polymers such as polyamides or SiLK™; other carbon-containing materials; organo-inorganic materials such as spin-on glasses and silsesquioxane-based materials; and diamond-like carbon (DLC, also known as amorphous hydrogenated carbon, a—C:H).

Vias are formed within the dielectric material using conventional photolithography and etching, in which interconnects to the low resistivity n-type and p-type silicide contacts 30, 35 are formed by depositing a conductive metal into the via holes using conventional processing.

Although not depicted in FIGS. 3-5, the first protective layer may alternatively be formed protecting the nFET device region, leaving the pFET device region exposed, wherein a low resistance p-type silicide is subsequently formed to the device contacts positioned within the pFET device region. Following removal of the first protective layer from the nFET device region, a second protective layer is formed overlying the low resistance p-type metal silicide in the pFET device region and a low resistance n-type metal silicide layer is formed atop the exposed nFET device region.

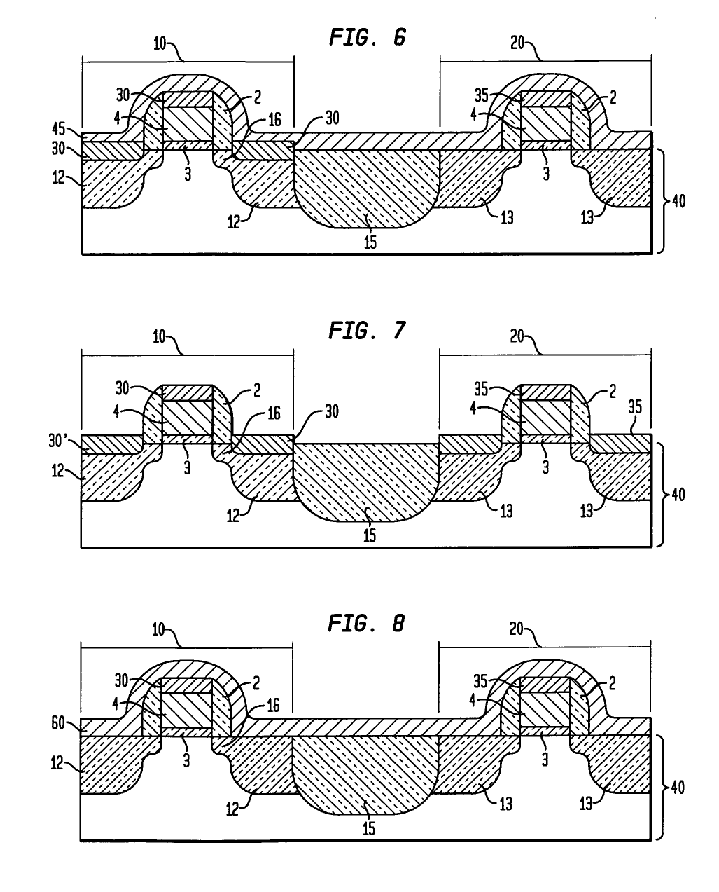

FIGS. 6-7 depict (through cross sectional view) a second embodiment of the inventive method for providing a CMOS structure having low resistance metal silicide contacts to pFET device regions and different low resistance metal silicide contacts to nFET device regions with the silicide differences tailored to improve contact resistances for the differing device types. Referring to FIGS. 6-7, the number of processing steps to provide a CMOS structure having low resistance n-type silicide contacts 30 to the nFET device region 10 and low resistance p-type silicide contacts 35 to the pFET device region 20 are reduced by eliminating use of one or more of the block masks and protective layers. For instance, the second protective layer utilized in the first embodiment of the present invention may be eliminated and a second metal layer blanket 45 deposited atop the first silicide layer (low resistance n-type silicide contact) in the first device region (n-type device region) and atop the substrate surface in the second device region (p-type device region). The second embodiment of the present invention is now described in greater detail.

Similar to the initial process steps depicted in FIGS. 3-4 of the first embodiment, a first silicide layer 30 (low resistance n-type silicide contact 30) is selectively formed atop the first device region 10 (the n-type device region 10) using deposition, photolithography and etch processes. Specifically, a first protective layer 81 is formed atop a portion of the substrate 40 leaving the nFET device region 10 exposed. A metal layer of a first silicide metal is then deposited atop the nFET device region that forms a low resistance n-type silicide contact during subsequently annealing. The first silicide metal preferably comprise CoSi₂, VSi₂, ErSi, ZrSi₂, HfSi, MoSi₂, CrSi₂ as well as others that have the work function substantially aligned to the conduction band of the nFet devices and produces a silicide having a work function substantially aligned with the conduction band of the n-type source/drain regions 12 in the nFET device region 10 of the substrate 40.

Referring now to FIG. 6, in the second embodiment of the present invention, following the formation of the low resistance n-type silicide contact 30, the first protective layer is removed from the substrate 40 and a second metal layer 45 is deposited directly atop the low resistance n-type silicide contact 30 in the nFET device region 10 and the substrate 40 surface of the pFET device region 20. The first protective layer is removed by a highly selective etch process that removes the first block mask without substantially etching the formed n-type silicide contact 30 or the surface of the p-type device region 20.

Following first protective layer removal, the surface of the low resistance n-type silicide contact 30 and the p-type device region 20 are then cleaned to provide a clean surface for silicidation. The cleaning process may be a conventional chemical clean as known within the skill of the art.

A second metal layer 45 is then deposited directly atop the pFET device region 20 and the low resistance n-type silicide contact 30. The second metal layer 45 comprises a second silicide metal that subsequently forms a silicide having a work function substantially aligned with the valence band of the p-type source/drain regions 13 within the pFET device region 20 of the substrate 40. The second metal layer 45 may be deposited using physical vapor deposition methods, such as sputtering and plating, and have a thickness ranging from about 1 nm to about 10 nm. The second metal layer 45 preferably comprises Pt, Ir, Pd, as well as others that have the work function substantially aligned to the valence band of the pFet devices.

Referring to FIG. 7, the second metal layer 45 is then annealed to produce a second silicide layer 35 having a work function substantially aligned with the valence band of the p-type source/drain regions 13 within the pFET device region 20 of the substrate 40, thus providing a low resistance p-type suicide contact 35. During annealing the second metal layer 45 intermixes with the low resistance n-type metal contact 30 within the nFET device region 10 forming a low resistance n-type metal silicide contact 30′ that may comprise Co, V, Er, Zr, Hf, Mo, Ni, Cr as well as others that have the work function substantially aligned to the conduction band of the nFet devices.

The incorporation of Pt positions the work function of the low resistance n-type silicide contact 30′ towards the center of the band gap and away from the conduction band of the n-type source/drain regions 12. However, despite the intermixing of Pt into the low resistance n-type metal contact 30, the work function of the low resistance n-type silicide contact 30′ is still substantially aligned with the conduction band of the n-type source/drain regions 12 and provides a contact having a low contact resistance ranging from about 10⁻⁹ ohm·cm⁻² to about 10⁻⁷ ohm·cm⁻².

Following silicidation, the unreacted portions of the second metal layer 45 are removed by a selective etch that does not substantially etch the structures within the nFET device region 10 and the pFET device region 20. Preferably, the unreacted Pt is removed with a chemical strip comprising nitric acid and HCI.

Similar to embodiment depicted in FIGS. 3-5, the first protective layer may alternatively be formed protecting the nFET device region, leaving the pFET device region exposed, wherein a low resistance p-type silicide contact comprising Pt is subsequently formed to the devices formed within the pFET device region 10. Following removal of the first protective layer from the nFET device region, a second metal layer comprising Co, V, Er, Zr, Hf, Mo, Ni, Cr is formed atop the low resistance p-type silicide contact and the exposed nFET device region, wherein a low resistance n-type silicide contact is formed to the devices formed within the nFET device region and the second metal layer intermixes with the low resistance p-type metal silicide contact during annealing.

Despite the incorporation of Co, V, Er, Zr, Hf, Mo, Ni, or Cr into the low resistance p-type silicide contact, the work function of the low resistance p-type silicide contact is still substantially aligned with the valence band of the p-type source/drain regions 13 and provides a contact having a low contact resistance ranging from 10⁻⁹ ohm·cm⁻² to about 10⁻⁷ ohm·cm⁻².

FIGS. 8-10 depict (through cross sectional view) a third embodiment of the inventive method for providing a CMOS structure having low resistance metal silicide contacts to pFET device regions and a different low resistance metal silicide contacts to nFET device regions with the silicide differences tailored to improve contact resistances for the differing device types. Referring to FIGS. 8-10, in a third embodiment of the present invention, the number of processing steps to provide a CMOS structure having low contact resistance n-type silicide contacts 30 to the nFET device region 10 and low resistance p-type suicide contacts 35 to the pFET device region 20 are further reduced by blanket depositing a first metal layer 60 directly atop the substrate 40 including the nFET and pFET device regions 10, 20. The third embodiment of the present invention is now discussed in greater detail.

Referring to FIG. 8, in a first process step a first metal layer 60 is blanket deposited directly atop the entire surface of the substrate 40 including the nFET device region 10 and the pFET device region 20. Prior to deposition, the surface of the substrate 40 is cleaned using a chemical cleaning composition comprising buffered HF; dilute HF; ammonium hydroxide-hydrogen peroxide; and/or hydrochloric acid-hydrogen peroxide.

The first metal layer 60 subsequently provides either a low resistance n-type silicide or a low resistance p-type silicide. A low resistance n-type metal silicide is formed by depositing a silicide metal, such as Co, V, Er, Zr, Hf, Mo, Ni, Cr which when silicided provides a work function substantially aligned to the conduction band of the n-type doped source/drain regions 12 of the substrate 40 in the nFET device region 10. A p-type metal silicide is formed by depositing a metal, Pt, Ir or Pd, which when silicided provides a work function that is substantially aligned to the valence band of the p-type doped source/drain regions 13 of the substrate 40 in the pFET device region 20. The first metal layer 60 may be deposited using physical deposition methods, such as plating and sputtering. In the embodiment depicted in FIGS. 8-10, the first metal layer 60 comprises Co, V, Er, Zr, Hf, Mo, Ni, or Cr.

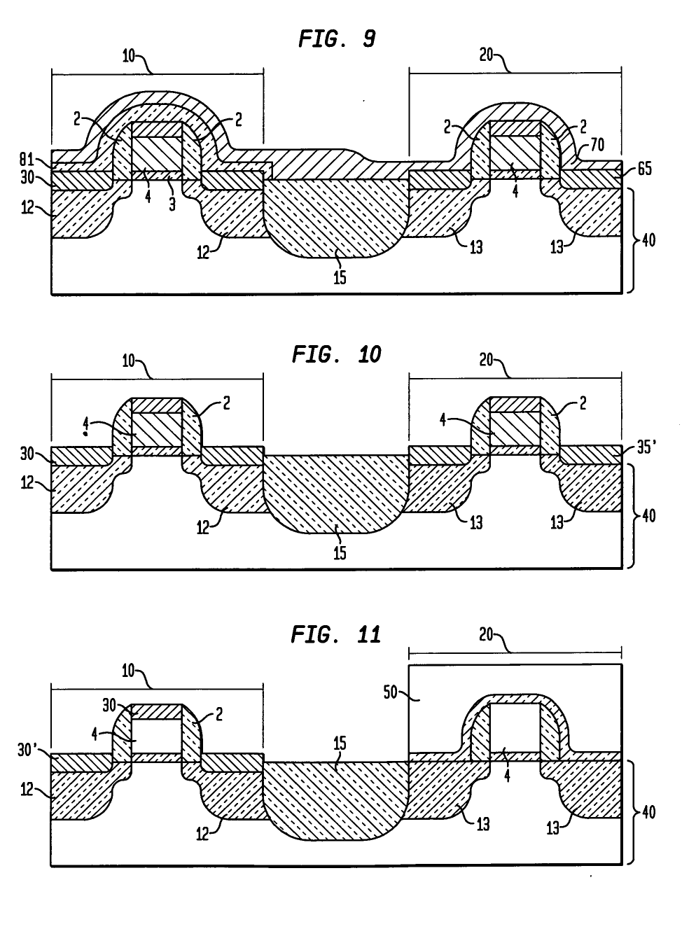

Referring to FIG. 9, following deposition, the first metal layer 60 is annealed to provide a low resistance n-type metal silicide contact 30 to the nFET device region 10. Similar to the first embodiment of the present invention, the first metal layer 60 is annealed using conventional annealing processes, such as rapid thermal annealing, at a temperature ranging from about 350° C. to about 600° C. for a time period ranging from about 1 second to about 90 seconds. During this silicidation process, the first metal layer 60 deposited atop the pFET device region 20 forms an initial silicide 65 in the pFET device region 20 comprising Co, V, Er, Zr, Hf, Mo or Cr. Following silicidation, the remaining unreacted first metal layer 60 is removed by a wet etch having selectivity to removing the remaining unreacted first metal layer 60 without substantially etching the nFET device region 10, the pFET device region 20 or the substrate 40.

Still referring to FIG. 9, a first protective layer 81 is then formed over the nFET device region 10 leaving the pFET device region 20 exposed. Similar to the previous embodiments, the first protective layer 81 preferably comprises silicon nitride and is formed using deposition, photolithography and etching, as described above with reference to FIG. 4. The surface of pFET device region 20 is then cleaned using a chemical clean to prepare the pFET device region 20 for silicidation. This cleaning process may be omitted since the initial silicide 65 is present in the pFET device region 20.

A second metal layer 70 is then blanket deposited atop the entire substrate 40 including the first protective layer 81 in the nFET device region 10 and atop the initial silicide 65 in the pFET device region 20. In the embodiment depicted in FIGS. 8-10, the second metal layer 70 comprises a metal that produces a silicide having a work function substantially aligned to the valence band of the p-type source/drain regions 13 in the pFET region 20 of the substrate 40, such as Pt, Ir, or Pd.

Following deposition, the second metal layer 70 is then annealed, wherein during annealing the second metal layer 70 intermixes with the initial silicide 65 to form a low resistance p-type silicide contact 35′ to the pFET device region 20. The low resistance p-type silicide 35′ contact comprises Pt, Ir, or Pd in combination with Co, V, Er, Zr, Hf, Mo, Ni, or Cr. The incorporation of Pt, Ir, or Pd positions the work function of the initial silicide contact 65 towards the valence band of the p-type source/drain regions 13 producing a low resistance p-type silicide contact 35. Despite the incorporation of Co, V, Er, Zr, Hf, Mo, Ni, or Cr with the Pt, Ir or Pd-silicide, the work function of the low resistance p-type silicide contact 35 is substantially aligned with the valence band of the p-type source/drain regions 13 and provides a contact having a low contact resistance ranging from about 10⁻⁹ ohm·cm⁻² to about 10^{-7 ohm·cm}⁻².

Silicide does not form atop the nFET device region 10, since the nFET device region 10 is protected by the first protective layer 81 and silicidation requires a Si-containing surface. Following silicidation, the unreacted portions of the second metal layer 70 and the first protective layer 81 are removed using a selective etch that does not substantially etch the structures within the nFET device region 10 and the pFET device region as depicted in FIG. 10.

In the embodiment depicted in FIGS. 8-10, the first metal layer may alternatively comprise a metal that provides a low resistance p-type silicide contact, such as Pt, Ir or Pd, that is deposited directly atop the nFET device region and the pFET device region, wherein the first metal layer is then annealed to provide a low resistance p-type metal silicide contact to the pFET device region and an initial silicide to the nFET device region, wherein the initial silicide to the nFET device region comprises Pt, Ir or Pd. The first protective layer may then be formed atop the pFET device region leaving the nFET device region exposed. A second metal layer comprising Co, V, Er, Zr, Hf, Mo, Ni or Cr can then be formed atop the exposed nFET device region including the initial silicide, wherein during annealing the second metal layer and the initial silicide intermix to provide a low resistance n-type metal silicide contact to the n-type device region.

PtSi, Pt₂Si, IrSi, Pd₂Si, as well as others that have the work function substantially aligned to the valence band of the pFet devices. The first-type silicide contact may comprise CoSi₂, VSi₂, ErSi, ZrSi₂, HfSi, MoSi₂, NiSi, CrSi₂ as well as others that have the work function substantially aligned to the conduction band of the nFet devices.

The incorporation of Co, V, Er, Zr, Hf, Mo, Ni, or Cr positions the work function of the initial silicide contact towards the conduction band of the n-type source/drain regions producing a low resistance n-type metal silicide contact. Despite the incorporation of Pt, Ir or Pd with the Co, V, Er, Zr, Hf, Mo, Ni, or Cr silicide, the work function of the low resistance n-type metal silicide contact is substantially aligned with the conduction band of the n-type source/drain regions and provides a contact having a low contact resistance ranging from about 10⁻⁹ ohm·cm⁻² to about 10⁻⁷ ohm·cm⁻².

In another embodiment of the present invention the silicided metal formed in the nFET device region and the pFET device region may be selected to provide strain based device improvements by increasing carrier mobility in pFET and nFET devices.

In a preferred embodiment, a semiconducting device is provided comprising a semiconducting substrate having a pFET region and an nFET region; in which the silicide contact to the devices within the nFET region produce a stress field that increases nFET device performance and the silicide contact to the devices within the pFET region produce a stress field within the pFET region that increases pFET device performance, wherein the stress field within the pFET region is more compressive than the stress field in the nFET region.

Carrier mobility may be increased in pFET devices by creating a compressive stress field in the substrate in which the pFET device is formed. Carrier mobility may be increased in nFET devices by creating a lower compressive stress within the nFET region than the pFET region or by forming a tensile stress in the nFET region.

Selective processing of the nFET and pFET regions of the substrate can be achieved using the any of the above-described methods, wherein instead of selecting process conditions and silicide metal compositions for the purposes of optimizing contact resistance the process conditions and silicide metal compositions are selected to provide strain based device improvements.

In one example, a stress differential is provided by depositing cobalt on the nFET region and a cobalt silicon alloy on the pFET region of the substrate, wherein following silicidation a cobalt disilicide contact is formed to the pFET and nFET devices. The method for forming the semiconducting device having a stress differential between nFET and pFET device regions is now discussed in greater detail with reference to FIG. 11.

Similar to the embodiment depicted in FIGS. 3-5, a semiconducting substrate 40 is provided including nFET device and pFET device regions 10, 20. A first protective layer 81 is then formed atop a second device region 20, i.e. pFET device region 20, leaving a first region, i.e. nFET device region 10, exposed.

The exposed device region is then processed to provide device silicide contacts that induce a stress field in the substrate that results in strain based device improvements in the devices formed thereon. For example, cobalt may be deposited atop the silicon containing surface of the nFET device region to provide metal silicide contacts that produce the appropriate stress field for strain based device improvements in nFET devices. Following deposition, the cobalt metal is annealed to convert the cobalt deposited atop the silicon surface of the nFET device region into an nFET metal silicide contact 30′. The stress state produced during silicidation of the cobalt can provide a low compressive to tensile stress state within the portion of the silicon containing substrate adjacent the nFET metal silicide contact 30′. Following silicidation the unreacted portion of the cobalt is removed by a selective etch process. The stress is thought to be due to the volumetric change of the resulting silicide compared to the reacted silicon. In the case of CoSi₂ the volume is of the silicide is 3% less than the reacted silicon, this is thought to create a mildly tensile stress which would be desirable for the mobility of carriers in nFets. Co₂Si converting to CoSi₂ by contrast has a silicide volume 29% greater than the reacted silicon of the substrate, this will create compressive stresses which improve the mobility of carriers in pFets.

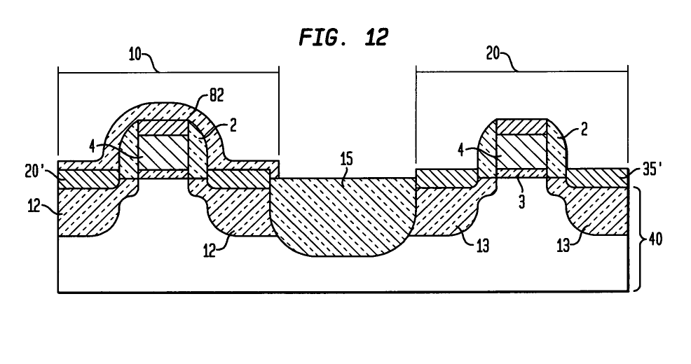

Referring now to FIG. 12, in a next series of process steps, a second protective layer 82 is formed atop the nFET device region 10 leaving the PFET region of the substrate 40 exposed. The PFET region 20 of the substrate 40 is then processed to provide PFET metal silicide contacts 35′ that induce a stress field in the substrate 40 that results in strain based device improvements in PFET devices. In one example, a cobalt silicide alloy (for example Co₂Si) is deposited on the exposed Si-containing surface of the pFET region 20 of substrate 40, wherein the stress state produced during silicidation of the cobalt silicon alloy can provide a highly compressive stress state within the portion of the substrate 40 adjacent the pFET metal silicide contact 35′.

The cobalt silicon alloy metal comprises from about 5 atomic weight % to about 25 atomic weight % silicon and 95 atomic weight % to about 75 atomic weight % cobalt. In a preferred embodiment, the cobalt silicon alloy is Co₂Si. It is noted that other silicon concentrations are also contemplated so long as the etch selectivity between the cobalt silicide alloy and the substrate 40 is maintained and a compressive stress is produced during the silicidation process within the pFET region 20 of the substrate 40. Following deposition, a low temperature anneal in the range of 300 C to 450 C converts the material to a more silicon rich silicide in areas contacting Si. Selective etchs can be used to remove the Co₂Si but not this more silicon rich silicide and a further anneal in the 600 C to 800 C will complete the conversion to CoSi₂ for the pFET silicide contact 35′.

The stress differential between the nFET device region 10 and pFET device 20 region of the semiconducting substrate results from the incorporation of Si into the deposited cobalt silicon alloy in the pFET region 20 of the substrate 40. In the present invention, depositing a cobalt alloy layer comprising Si reduces the amount of silicon that is required from the silicon containing substrate to silicide the cobalt alloy layer. By removing less silicon from the silicon lattice of the substrate during silicidation of the cobalt alloy, a volumetric expansion occurs that results in an increase in the compressive strain adjacent to the subsequently formed pFET metal silicide contact. As mentioned earlier the volume difference between the CoSi₂ formed and the silicon reacted from the substrate is approx 29% greater volume after reaction. This will create a compressive stress that will aid the mobility of the pFet carriers.

In another embodiment of the present invention, the pFET device region 20 of the substrate 40 may be processed to provide a platinum silicide. In this embodiment of the present invention the stress differential between the pFET device region 20 and the nFET device region 10 is created by forming a cobalt silicide or cobalt disilicide contact in the nFET device region 10 of the substrate 40 and forming a silicide comprising platinum and cobalt in the pFET device region. The cobalt silicide or cobalt disilicide in the nFET device region of the substrate produces a low compressive or tensile stress field within nFET region 10 and therefore increases carrier mobility and device performance in nFET devices. The silicide comprising platinum and cobalt produces a compressive stress field within the pFET device region and therefore increases carrier mobility and device performance in pFET devices.

These are just 2 examples of materials for optimizing stress in pFets. Examples of suicides that optimize stress in each device are listed. For example CoSi₂ has a ratio of silicide volume to silicon consumed of 0.97 which should produce a mildly tensile stress and will benefit the mobility of an nFet. PtSi has a ratio of silicide volume to silicon consumed of 1.5 which should produce a compressive stress and will benefit the mobility of a pFet. Further examples of suicides with a ratio of silicide volume to silicon consumed that would favor mobility in nfets would be CrSi₂ with a ratio of 0.9, IrSi₃ with a ratio of 0.9 and MoSi₂ with a ratio of 0.87, other suicides will also meet this criteria. Further examples of suicides with a ratio of silicide volume to silicon consumed that would favor mobility in pfets would be PdSi with a ratio of 1.45, RhSi with a ratio of 1.35 and YSi with a ratio of 2.13, other suicides will also meet this criteria.

Another way to create this stress differential would be to create 2 phases of silicide from the same base metal, for example Zr₂Si has a ratio of 2.7 and would favor pFets and Zr₅Si₃ has a ratio of 0.25 and would favor nFets.

Yet another method to create this stress differential would be to deposit Co on the nFets and form CoSi₂ with a ratio of 0.97 and deposit a Co alloy with 5% to 25% silicon, which for example depositing Co₂Si to form CoSi₂ would have a ratio of approx 1.29 which would produce a stress favoring the pFets.

While the present invention has been particularly shown and described with respect to preferred embodiments thereof, it will be understood by those skilled in the art that the foregoing and other changes in forms and details may be made with departing from the spirit and scope of the present invention. It is therefore intended that the present invention not be limited to the exact forms and details described and illustrated, but fall within the scope of the appended claims.

1. A semiconducting structure comprising:
a substrate having a p-type device including a drain, source and gate contact region in a first device region and an n-type device including a drain, source and gate contact region in a second device region;
a first-type silicide contact formed at each said drain, source and gate contact region of said n-type device in said second device region; said first-type silicide having a work function that is substantially aligned to a conduction band of said n-type device in said second device region; and
a second-type silicide contact formed at each said drain, source and gate contact region of said p-type device in said first device region; said second-type silicide having a work function that is substantially aligned to a valence band of said p-type device in said first device region.

2. The semiconducting structure of claim 1 wherein said second-type silicide contact is selected from the group consisting of PtSi, Pt₂Si, IrSi, and Pd₂Si, and the first-type silicide contact is selected from the group consisting of CoSi₂, VSi₂, ErSi, ZrSi₂, HfSi, MoSi₂, NiSi, and CrSi₂.

3. The semiconducting structure of claim 1 wherein said first-type silicide contact has a contact resistance ranging from substantially 10⁻⁹ ohm·cm⁻² to 10^{-7 ohm·cm}⁻² and said second-type silicide contact has a contact resistance ranging from substantially 10⁻⁹ ohm·cm⁻² to 10^{-7 ohm·cm}⁻².

4. A method for forming a semiconducting structure comprising:
forming a first silicide layer on at least a first region of a substrate, said first region of said semiconducting substrate comprising first conductivity type devices, wherein said first silicide layer has a work function substantially aligned with a conduction band of said first conductivity type devices; and
forming a second silicide layer on at least a second region of said substrate, said second region of said substrate comprising second conductivity type devices, wherein said second silicide layer has a work function substantially aligned with a valence band of said second conductivity type devices.

5. The method of claim 4 wherein said first region of said substrate comprises at least one nFET device and said second region of said substrate comprises at least one pFET device.

6. The method of claim 5 wherein said second silicide layer is selected from the group consisting of PtSi, Pt₂Si, IrSi, and Pd₂Si, and said first silicide layer is selected from the group consisting of CoSi₂, VSi₂, ErSi, ZrSi₂, HfSi, MoSi₂, NiSi, and CrSi₂.

7. The method of claim 6 wherein said second silicide layer further comprises a material selected from the group consisting of Co, Er, V, Zr, Hf, Mo, Ni, Cr, and combinations thereof, and said first silicide layer further comprises a material selected from the group consisting of Pt, Pd, Ir, and combinations thereof.

8. The method of claim 5 wherein said forming said first silicide layer on said first region of said substrate further comprises:
forming a first protective layer on said substrate, said first protective layer protecting said second region of said substrate and exposing said first region of said substrate;
depositing a first silicide metal on at least said first region of said substrate;
annealing said substrate to convert said first silicide metal to said first silicide layer;
removing said first protective layer.

9. The method of claim 8 wherein said first silicide metal is selected from the group consisting of Co, Er, V, Zr, Hf, Mo, Ni, and Cr.

10. The method of claim 9 wherein said forming said second silicide layer on said second region of said substrate further comprises:
forming a second protective layer on said substrate, said second protective layer protecting said first region of said substrate and exposing said second region of said substrate;
depositing a second silicide metal on said second region of said substrate;
annealing second silicide metal to convert said second silicide metal to said second silicide layer,
removing said second protective layer.

11. The method of claim 10 wherein said second silicide metal is selected from the group consisting of Pt, Ir, and Pd.

12. The method of claim 11 wherein said forming a second silicide metal on said second region of said substrate comprises depositing a second silicide metal on said second region and atop said first silicide layer; and
annealing said second silicide metal to convert said second silicide metal atop said second region to said second silicide layer and diffuse said second silicide metal atop said first region into said first silicide layer.

13. The method of claim 12 wherein said second silicide metal is selected from the group consisting of Pt, Ir, and Pd.

14. The method of claim 5 wherein forming said first silicide layer on said first region of said substrate further comprises depositing a first silicide metal on said first region and said second region of said substrate; and annealing said first silicide metal to form said first silicide layer.

15. The method of claim 14 wherein said forming said second silicide layer on said second device region comprises forming a protective layer over said first silicide layer in said first region of said substrate; and
depositing a second silicide metal atop said first silicide layer in said second region of said substrate; and annealing second silicide metal to diffuse said second silicide metal into said first silicide layer atop in said second region of said substrate to provide a second silicide layer.

16. The method of claim 17 wherein said first silicide metal is selected from the group consisting of Co, Er, V, Er, Zr, Hf, Mo, Ni, Cr, and Er and said second silicide metal is selected from the group consisting of Pt, Ir, and Pd.

17. A semiconducting device comprising:
a semiconducting substrate having a first region and a second region;
at least one first type device comprising a first gate region atop a first device channel portion of said semiconducting substrate within said first region and source and drain regions in said first region adjacent said first device channel portion and a first-type silicide contact formed at each said source and drain regions adjacent said first device channel portion, said first silicide contact producing a first strain in said first region of said semiconducting substrate; and
at least one second type device comprising a second gate region atop a second device channel portion of said semiconducting substrate within said second region, source and drain regions in said second region adjacent said second device channel portion and a second-type silicide contact formed at each said source and drain regions adjacent said second device channel portion, said second silicide contact producing a second strain in said second region of said substrate, wherein said first strain and said second strain are compressive strains and said first compressive strain is greater than said second compressive strain, or said first strain is a compressive strain and said second strain is a tensile strain, or said first strain is a tensile strain and said second strain is a tensile strain and said first tensile strain is less than said second tensile strain.

18. The semiconducting device of claim 17 wherein said at least one first type device is a pFET and said at least one second type device is an nFET.

19. The semiconducting device of claim 17 wherein said first silicide contact is selected from the group consisting of PtSi, PdSi, CoSi₂, and Zr₂Si where the ratio of the silicide volume to the reacted silicon in the substrate is greater than 1, and said second silicide contact is selected from the group consisting of CoSi₂, IrSi₃, CrSi₂, MoSi₂, and Zr₅Si₃ where the ratio of the silicide volume to the reacted silicon in the substrate is less than the ratio of the first silicide.

20. A method for forming a semiconducting structure comprising:
forming a first silicide layer on at least a first region of a substrate, said first region of said semiconducting substrate comprising first conductivity type devices, said first silicide layer producing a first strain within said first region of said semiconducting substrate; and
forming a second silicide layer on at least a second region of said substrate, said second region of said substrate comprising second conductivity type devices, said first silicide layer produces a second strain within said second region of said semiconducting substrate, wherein said first strain is different from said second strain.

21. The method of claim 20 wherein said first strain increases carrier mobility in pFET devices and said second strain increases carrier mobility in nFET devices.

22. The method of claim 21 wherein said forming said first silicide layer on said first region of said substrate further comprises:
forming a first protective nitride layer on said substrate, said first protective nitride layer protecting said second region of said substrate and exposing said first region of said substrate;
depositing a first silicide metal on at least said first region of said substrate;
annealing said substrate to convert said first silicide metal to said first silicide layer; and
removing said first protective nitride layer.

23. The method of claim 22 wherein said first silicide metal is a cobalt silicon alloy comprising 5% to 25% silicon and 95% to 75% cobalt by atomic weight percent.

24. The method of claim 22 wherein said first silicide is selected from the group consisting of PtSi, PdSi, CoSi₂, and Zr₂Si where the ratio of the silicide volume to the reacted silicon in the substrate is greater than 1.

25. The method of claim 23 wherein said forming said second silicide layer on said second region of said substrate further comprises:
forming a second protective nitride layer on said substrate, said second protective nitride layer protecting said first region of said substrate and exposing said second region of said substrate;
depositing a second silicide metal on said second region of said substrate;
annealing second silicide metal to convert said second silicide metal to said second silicide layer,
removing said second protective nitride layer.

26. The method of claim 25 wherein said second silicide is selected from the group consisting of CoSi₂, IrSi₃, CrSi₂, MoSi₂, and Zr₅Si₃ where the ratio of the silicide volume to the reacted silicon in the substrate is less than the ratio of the first silicide.

27. The method of claim 24 wherein said forming said second silicide layer on said second region of said substrate further comprises:
forming a second protective nitride layer on said substrate, said second protective nitride layer protecting said first region of said substrate and exposing said second region of said substrate;
depositing a second silicide metal on said second region of said substrate;
annealing second silicide metal to convert said second silicide metal to said second silicide layer;
removing said second protective nitride layer.

28. The method of claim 27 wherein said second silicide is selected from the group consisting of CoSi₂, IrSi₃, MoSi₂, and Zr₅Si₃ where the ratio of the silicide volume to the reacted silicon in the substrate is less than the ratio of the first silicide.
